(19) United States
(12) Patent Application Publication
(10) Pub. No.: US 2021/0071313 A1
(43) Pub. Date: Mar. 11, 2021

(54) CRYSTAL GROWTH APPARATUS

(71) Applicant: ZING SEMICONDUCTOR CORPORATION, Shanghai (CN)

(72) Inventors: Weimin Shen, Shanghai (CN); Gang Wang, Shanghai (CN)

(21) Appl. No.: 17/016,443

(22) Filed: Sep. 10, 2020

(30) Foreign Application Priority Data
Sep. 11, 2019 (CN) 201910860787.1

(51) Int. Cl. C30B 15/14; C30B 29/06

(52) U.S. Cl. CPC C30B 15/14; C30B 29/06

(57) ABSTRACT

The present invention provides a crystal growth apparatus, which comprises a crucible, which is configured to contain a melt for a crystal growth; a heater, which is disposed around the crucible and configured to heat the crucible; and a heat soaking sleeve, which is disposed between the heater and the crucible, in which a side wall of the heat soaking sleeve comprises a thick-walled region and a thin-walled region, the thin-walled region is disposed corresponding to a high temperature region, and the thick-walled region is disposed corresponding to a low temperature region.

### CROSS-REFERENCE TO RELATED APPLICATIONS

This application claims priority to P.R.C. Patent Application No. 201910860787.1 titled “Crystal growth apparatus” filed on Sep. 11, 2019, with the State Intellectual Property Office of the People's Republic of China (SIPO).

### TECHNICAL FIELD

The present disclosure relates to a crystal growth apparatus.

### BACKGROUND

With the remarkable development of integrated circuit (IC) industry, component manufacturers have put stricter demands regarding IC grade single crystal silicon materials, and large diameter single crystal silicon is a necessary substrate material for the preparation of components. The Czochralski Process (CZ) method is the most important method for growing single crystals from the melt in the prior art, in which the specific method is to heat and melt the raw materials constituting the crystal in a quartz crucible, then a seed crystal is pulled from the liquid level of the silicon melt. Under controlled conditions, atoms or molecules are continuously rearranged at the interface between the seed crystal and the melt, and the crystal grows as the temperature gradually solidifies.

In the existing crystal growth apparatus, a heater is arranged around a crucible. However, a ring heater generally adopts a plurality of heaters arranged at intervals or only a part of the heaters is heated by electricity. Therefore, the temperature distribution of the silicon melt are not uniform in the circumferential direction. For example, the temperature of the heater in the circumferential direction of a certain height position will show a high-low-high-low change, and the thermal radiation causes periodic changes in the surface temperature of the rotating graphite crucible, such that the graphite crucible has thermal cycling stress, which shortens the service life of the crucible.

### SUMMARY

A series of simplified forms of concepts are introduced in the summary section, which will be explained in further detail in the detailed description section. The summary of the present invention does not mean trying to define the key features and necessary technical features of the claimed technical solution, let alone trying to determine the protection scope of the claimed technical solution.

In order to solve the problems in the prior art, the invention provides a crystal growth apparatus, comprises:
a crucible, which is configured to contain a melt for a crystal growth;
a heater, which is disposed around the crucible and configured to heat the crucible; and
a heat soaking sleeve, which is disposed between the heater and the crucible, in which a side wall of the heat soaking sleeve comprises a thick-walled region and a thin-walled region, the thin-walled region is disposed corresponding to a high temperature region, and the thick-walled region is disposed corresponding to a low temperature region.

In accordance with some embodiments, a distance between an inner wall of the thick-walled region and the crucible is smaller than a distance between an inner wall of the thin-walled region and the crucible.

In accordance with some embodiments, the high temperature region comprises the heater or a heating region of the heater, and the heating region of the heater comprises powered electrodes.

In accordance with some embodiments, the low temperature region comprises an interval between the heaters or a non-heating region of the heater, and the non-heating region of the heater comprises non-powered electrodes.

In accordance with some embodiments, a range of thickness difference between the thick-walled region and the thin-walled region is from 2 mm to 10 mm.

In accordance with some embodiments, the heat soaking sleeve is equally divided into a plurality of the thick-walled regions and a plurality of the thin-walled regions, and the thick-walled regions and the thin-walled regions are alternately arranged.

In accordance with some embodiments, the heat soaking sleeve is an integral structure or is composed of a plurality of separate parts.

In accordance with some embodiments, a material of the heat soaking sleeve includes graphite or graphite carbon fiber material.

According to the crystal growth apparatus provided in the present invention, by setting a heat soaking sleeve between the heater and the crucible, in which the side wall of the heat soaking sleeve comprises a thick-walled region and a thin-walled region, and using the difference in wall thickness to adjust the radiation energy from the heater to the graphite crucible to balance the temperature effect, the heat radiated from the crystal growth apparatus during the rotation of the graphite crucible is as much as possible.

### BRIEF DESCRIPTION OF THE DRAWINGS

Exemplary embodiments will be more readily understood from the following detailed description when read in conjunction with the appended drawings, in which:

FIG. 1 depicts a schematic diagram of a crystal growth apparatus according to one embodiment of the present disclosure.

FIG. 2 depicts a cross-section view of a crystal growth apparatus according to one embodiment of the present disclosure.

### DETAILED DESCRIPTION

In the following description, numerous specific details are given to provide a more thorough understanding of the present invention. However, it will be apparent to one skilled in the art that the present invention may be practiced without one or more of these details. In other examples, in order to avoid confusion with the present invention, some technical features known in the art are not described.

For a thorough understanding of the present invention, a detailed description will be provided in the following description to illustrate the method according to the present invention. Obviously, the implementation of the present invention is not limited to the specific details familiar to those skilled in the semiconductor field. The preferred embodiments of the present invention are described in detail below. However, in addition to these detailed descriptions, the present invention may have other embodiments.

It should be noted that terminology used herein is for the purpose of describing particular embodiments only and is not intended to limit the exemplary embodiments according to the present invention. As used herein, the singular forms are intended to comprise the plural forms as well, unless the context clearly indicates otherwise. In addition, it should also be understood that when the terms “including” and/or “including” are used in this specification, they indicate the presence of stated features, integers, steps, operations, elements and/or components, but do not exclude the presence or Add one or more other features, wholes, steps, operations, elements, components, and/or combinations thereof.

Now, exemplary embodiments according to the present invention will be described in more detail with reference to the accompanying drawings. These exemplary embodiments may, however, be embodied in many different forms and should not be construed as limited to the embodiments set forth herein. It should be understood that these embodiments are provided so that this disclosure will be thorough and complete, and will fully convey the concept of the exemplary embodiments to those skilled in the art. In the drawings, the thicknesses of layers and regions are exaggerated for the sake of clarity, and the same elements are denoted by the same reference numerals, and their descriptions will be omitted.

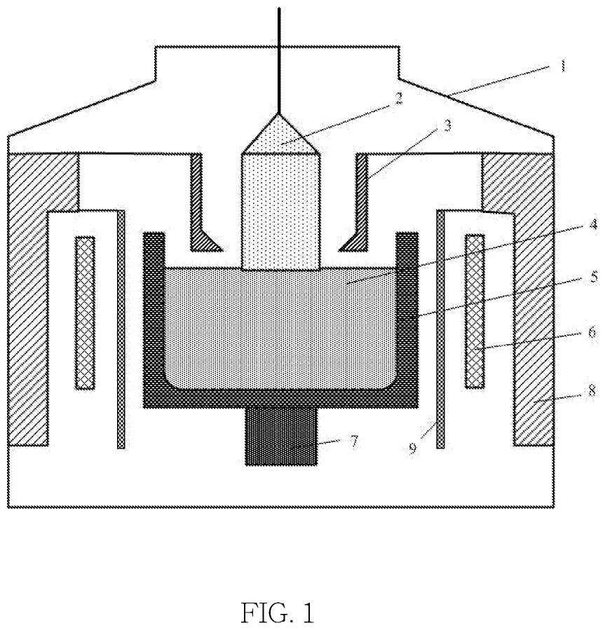

Referring to FIG. 1, FIG. 1 is a schematic diagram of a crystal growth apparatus according to one embodiment of the present disclosure. The crystal growth apparatus may comprises a furnace body 1, a crucible 5, a heater 6, and a reflection shield 3. The crucible 5 may be disposed in the furnace body 1. The heater 6 may be disposed around the outside of the crucible 5. The crucible 5 may contain a melt 4, in which an upper part of the melt 4 may be a crystal 2. The reflection shield 3 may be disposed above the crucible 5 and surround the crystal 2. For example, the melt 4 in the crucible 5 may be a silicon melt, and the grown crystal 2 may be a single crystal silicon rod.

For example, the furnace body 1 may be a stainless steel cavity, and the furnace body 1 may be vacuum or filled with protective gas. In one embodiment, the protective gas may be Argon, whose purity may be above 97%, pressure may be 5 mbar-100 mbar, and flow rate may be 70 slpm −200 slpm.

For example, the crucible 5 is made of a material resistant to high temperature and corrosion, and the crucible 5 contains a melt for crystal growth. In one embodiment, the crucible 5 may comprise a quartz crucible and/or graphite crucible, and the crucible 5 may contain a silicon material, such as polycrystalline silicon. The silicon material is heated in the crucible 5 into a silicon melt for growing a single crystal silicon rod. Specifically, the seed crystal is immersed in the silicon melt, a seed crystal axis may drive the seed crystal to rotate and be pulled, so that the silicon atom grow along the seed crystal into the single crystal silicon rod. The seed crystal may be cut or drilled from the single crystal silicon with a certain crystal orientation. Commonly used crystal orientations are <100>, <111>, <110>, etc. The seed crystal is generally a cylinder.

For example, the heater 6 is disposed around the crucible 5. The heater 6 is a graphite heater, which is arranged on the lateral surface of the crucible 5, and configured to heat the crucible 5. Further, the heater 6 includes one or more heaters arranged around the crucible 5, so that the thermal field of the crucible 5 is evenly distributed.

For example, the furnace body 1 is also provided with the reflection shield 3, which is disposed is disposed above the crucible 5, and is located outside the crystal 2 around the crystal 2 to prevent the heat of the melt 4 from being transferred to the furnace body 1 in the form of heat radiation, etc. the heat loss.

Further, the crustal growth apparatus further includes a crucible lifting mechanism 7 configured to support and rotate the crucible shaft to achieve the lifting and lowering of the crucible 5.

Further, the crystal growth apparatus also includes a heat insulation structure 8 disposed on the inner side of the side wall of the furnace body 1 to prevent heat loss and achieve thermal insulation of the furnace body 1. As shown in FIG. 1, the reflective shield 3 is connected to the heat insulating structure 8 through the fixing structure to fix the reflective shield 3 above the crucible 5.

However, in the prior art, the heating region in the circumferential direction is not uniform, which is caused by arranging a plurality of heaters at intervals or heating only a part of the position in one heater by electricity. In one embodiment, the heater 6 is a single ring-shaped heater, which is arranged around the crucible 5, but the ring-shaped heater is equipped with a plurality of graphite electrodes (for example, four electrode holders) fixed at four electrode positions of the furnace body 1, in which the two electrodes facing each other are supplied with heating current, and the other two are only used for fixing the heater 6. The electrodes of the furnace body 1 uses water cooling to reduce the temperature of the metal copper electrodes, so the temperature of the region where the electrodes are not powered is lower than the temperature of the region where the electrodes are powered. Therefore, at a certain height position, the temperature distribution on the circumferential direction shows a high-low-high-low change, and the temperature change causes the heat radiated to the crucible 5 to fluctuate, such that the crucible 5 has a thermal cycling stress and the service life of the crucible 5 is shorten.

Regarding the above problems, the present invention provides a crystal growth apparatus, including:
a crucible 5, configured to contain a melt 4 for a crystal growth;
a heater 6, which is disposed around the crucible 5 and configured to heat the crucible 5; and
a heat soaking sleeve 9, which is disposed between the heater 6 and the crucible 5, wherein a side wall of the heat soaking sleeve 9 comprises a thick-walled region and a thin-walled region, the thin-walled region is disposed corresponding to a high temperature region, and the thick-walled region is disposed corresponding to a low temperature region.

For example, the thickness of the side wall of the thick-walled region is greater than the thickness of the side wall of the thin-walled region. In one embodiment, a range of the thickness difference between the thick-walled region and the thin-walled region is from 2 mm to 10 mm.

For example, the thin-walled region is arranged corresponding to a high temperature region, and the thick-walled region is arranged corresponding to a low temperature region. The high temperature region comprises the heater or a heating region of the heater, and the heating region of the heater comprises powered electrodes. The low temperature region comprises an interval between the heaters or a non-heating region of the heater, and the non-heating region of the heater includes non-powered electrodes.

In one embodiment, a plurality of heaters 6 are provided, in which the region corresponding to each one of the heaters 6 is the high temperature region, and the interval region between the heaters 6 is a low temperature region. In another embodiment, a heater 6 is provided, in which the powered heating region is the high temperature region, and the non-powered non-heating region is the low temperature region.

For example, the distance between the outer wall of the heat soaking sleeve 9 and the heater 6 is equal everywhere. A distance between an inner wall of the thick-walled region and the crucible 5 is smaller than a distance between an inner wall of the thin-walled region and the crucible 5.

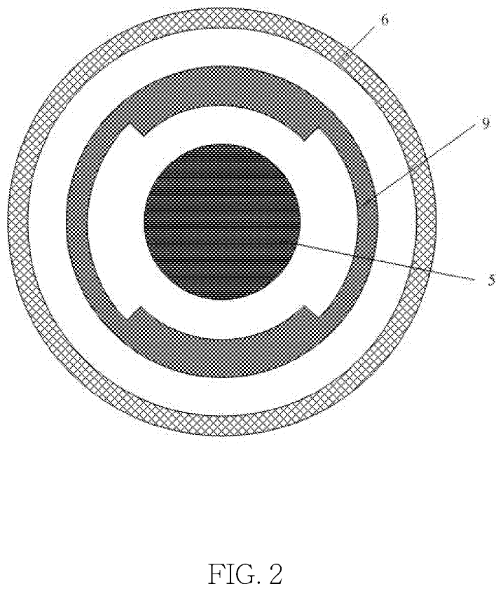

In one embodiment, as shown in FIG. 2, the cross-sections of the heater 6 and the crucible 5 are circular rings, such that the cross-sections of the outer wall of the heat soaking sleeve 9 is also a circular ring, and the circle center of the heater 6 and that of the heat soaking sleeve 9 coincide so as to realize that the distance between the outer wall of the soaking sleeve 9 and the heater 6 is equal everywhere. However, since the heat soaking sleeve 9 includes a thick-walled region and the thin-walled region, the thickness of the side wall of the thick-walled region is greater than that of the thin-walled region. Therefore, the cross section of the inner wall of the soaking sleeve 9 is an irregular shape like a gear, in which the inner wall of the thick-walled region is closer to the crucible 5, and the inner wall of the thin-walled region is far from the crucible 5.

Since the thick-walled region is arranged corresponding to the low-temperature region, it receives less heat radiation, but the distance between the inner wall of the thick-walled region and the crucible 5 is smaller, and the radiation shape factor is larger. Since the thin-walled region is arranged corresponding to the high-temperature region, it receives more heat radiation, but the distance between the inner wall of the thin-walled area and the crucible 5 is larger, and the radiation shape factor is smaller. Therefore, by increasing the radiation shape factor of the thick-walled region, the relatively low temperature effect can be balanced, so that the heat radiated from the heater 6 to the heat soaking sleeve 9 during the rotation of the crucible is as uniform as possible.

By reducing the thermal cycling stress of the crucible 5, the service life of the crucible 5 is extended. Specifically, the usage count of graphite crucibles may be extended from 30 to more than 60. Besides, by reducing the temperature change on the circumferential direction of the crucible 5, the crystal growth process is more stable and reliable.

For example, the heat soaking sleeve 9 is equally divided into a plurality of the thick-walled regions and a plurality of the thin-walled regions, in which the thick-walled regions and the thin-walled regions are alternately arranged.

In one embodiment, the number of the thick-walled regions and the number of the thin-walled regions depend on the number of heaters 6 or the number of heating regions in the heater 6. As shown in FIG. 2, the heater 6 has two heating regions arranged oppositely, and two thin-walled regions are designed accordingly; two thick-walled regions are designed accordingly in the non-heating region between the two heating regions. Therefore, the thick-walled regions and the thin-walled regions are always arranged alternately. Besides, the length of each one of the thick-walled regions can be the same or different. The length of each one of the thin-walled regions can be the same or different. The length of one of the thick-walled regions and that of one of the thin-walled regions may be the same or different. Preferably, the heat soaking sleeve 9 is equally divided into a plurality of thick-walled regions and a plurality of thin-walled regions, that is, each thick-walled region and each thin-walled region have the same length.

For example, the heat soaking sleeve 9 is an integral structure or is composed of a plurality of separate bodies. In one embodiment, the heat soaking sleeve 9 is designed in an integrated design and is directly formed. In another embodiment, the heat soaking sleeve 9 is formed by splicing and combining multiple thick-walled regions and multiple thin-walled regions.

For example, the material of the heat soaking sleeve 9 includes thermal insulation material. In one embodiment, the material of the heat soaking sleeve 9 is high-purity graphite. In another embodiment, the heat soaking sleeve 9 is made of carbon/carbon composite material, in which carbon/carbon composites are carbon matrix composites reinforced with carbon fibers and their fabrics, which has the advantages of low density, high strength, high specific modulus, high thermal conductivity, low expansion coefficient, good friction performance, good thermal shock resistance and high dimensional stability.

As shown in FIG. 1, the heat soaking sleeve 9 is connected to the heat insulating structure 8 through the fixing structure to fix the heat soaking sleeve 9 around the crucible 5.

According to the crystal growth apparatus provided in the present invention, by setting the heat soaking sleeve between the heater and the crucible, in which the side wall of the heat soaking sleeve comprises the thick-walled region and the thin-walled region, and using the different wall thickness adjustment radiation shape factor to balance the temperature effect, the heat radiated from the crystal growth apparatus during the rotation of the graphite crucible is as much as possible.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A crystal growth apparatus, comprising:
a crucible, configured to contain a melt for a crystal growth;
a heater, disposed around the crucible and configured to heat the crucible; and
a heat soaking sleeve, disposed between the heater and the crucible, wherein a side wall of the heat soaking sleeve comprises a thick-walled region and a thin-walled region, the thin-walled region is disposed corresponding to a high temperature region, and the thick-walled region is disposed corresponding to a low temperature region.

2. The apparatus according to claim 1, wherein a distance between an inner wall of the thick-walled region and the crucible is smaller than a distance between an inner wall of the thin-walled region and the crucible.

3. The apparatus according to claim 1, wherein in the high temperature region comprises the heater or a heating region of the heater, and the heating region of the heater comprises powered electrodes.

4. The apparatus according to claim 1, wherein the low temperature region comprises an interval between the heaters or a non-heating region of the heater, and the non-heating region of the heater comprises non-powered electrodes.

5. The apparatus according to claim 1, wherein a range of thickness difference between the thick-walled region and the thin-walled region is from 2 mm to 10 mm.

6. The apparatus according to claim 1, wherein the heat soaking sleeve is equally divided into a plurality of the thick-walled regions and a plurality of the thin-walled regions, and the thick-walled regions and the thin-walled regions are alternately arranged.

7. The apparatus according to claim 1, wherein the heat soaking sleeve is an integral structure or is composed of a plurality of separate parts.

8. The apparatus according to claim 1, wherein a material of the heat soaking sleeve comprises graphite or graphite carbon fiber material.
